(19) United States
(12) Patent Application Publication
(10) Pub. No.: US 2022/0190103 A1
(43) Pub. Date: Jun. 16, 2022

(54) CAPACITOR MANUFACTURING METHOD

(71) Applicant: STMICROELECTRONICS (TOURS) SAS, Tours (FR)

(72) Inventor: Mohamed BOUFNICHEL, Monnaie (FR)

(73) Assignee: STMICROELECTRONICS (TOURS) SAS, Tours (FR)

(21) Appl. No.: 17/542,170

(22) Filed: Dec. 3, 2021

(30) Foreign Application Priority Data
Dec. 14, 2020 (FR) 2013214

(51) Int. Cl. H01L 49/02

(52) U.S. Cl. CPC H01L 28/88; H01L 28/92

(57) ABSTRACT

The present description concerns a capacitor manufacturing method, including the successive steps of: a) forming a stack including, in the order from the upper surface of a substrate, a first conductive layer made of aluminum or an aluminum-based alloy, a first electrode, a first dielectric layer, and a second electrode; b) etching, by chemical plasma etching, an upper portion of the stack, said chemical plasma etching being interrupted before the upper surface of the first conductive layer; and c) etching, by physical plasma etching, a lower portion of the stack, said physical plasma etching being interrupted on the upper surface of the first conductive layer.

### BACKGROUND

### Technical Field

The present disclosure generally relates to the manufacturing of an integrated circuit, and more particularly at the manufacturing of an integrated circuit comprising a capacitor, for example, a passive integrated circuit.

### Description of the Related Art

Various methods of manufacturing integrated circuits comprising capacitors have been provided. These methods have various disadvantages. It would be desirable to have a method of manufacturing an integrated circuit comprising a capacitor, this method overcoming all or part of the disadvantages of known methods.

### BRIEF SUMMARY

An embodiment provides a method of manufacturing a capacitor, comprising the successive steps of:

a. forming a stack comprising, in the order from the upper surface of a substrate, a first conductive layer made of aluminum or an alloy based on aluminum, a first electrode, a first dielectric layer, and a second electrode;

b. etching, by chemical plasma etching, an upper portion of the stack, said chemical plasma etching being interrupted before the upper surface of the first conductive layer; and

c. etching, by physical plasma etching, a lower portion of the stack, said physical plasma etching being interrupted on the upper surface of the first conductive layer.

According to an embodiment, said chemical plasma etching, at step b), comprises a first step of chemical plasma etching by means of a chlorine-based plasma, followed by a second step of chemical plasma etching by means of a fluorine-based plasma.

According to an embodiment, the second chemical plasma etching step and the physical plasma etching step are implemented in a same etch chamber, a step of purging of said etch chamber being implemented between the two steps.

According to an embodiment, said chemical plasma etching, at step b), comprises a single step of chemical plasma etching by means of a chlorine-based plasma.

According to an embodiment, said chemical plasma etching, at step b), comprises a single step of chemical plasma etching by means of a fluorine-based plasma.

According to an embodiment, the stack further comprises a second conductive layer coating the second electrode.

According to an embodiment, the physical plasma etching, at step c), is carried out by means of an argon plasma.

According to an embodiment, the second conductive layer is made of aluminum or of an alloy comprising aluminum.

According to an embodiment, the first electrode is made of tantalum nitride.

According to an embodiment, said lower portion of the stack comprises at least a portion of the thickness of the first electrode.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 is a simplified cross-section view of an example of a capacitor according to an embodiment;

FIG. 2 is a cross-section view illustrating a step of a method of manufacturing the capacitor of FIG. 1;

FIG. 3 is a cross-section view illustrating another step of a method of manufacturing the capacitor of FIG. 1;

FIG. 4 is a cross-section view illustrating another step of a method of manufacturing the capacitor of FIG. 1;

FIG. 5 is a cross-section view illustrating another step of a method of manufacturing the capacitor of FIG. 1;

FIG. 6 is a cross-section view illustrating a step of a method of manufacturing the capacitor of FIG. 1 according to a first embodiment;

FIG. 7 is a cross-section view illustrating another step of a method of manufacturing the capacitor of FIG. 1 according to the first embodiment;

FIG. 8 is a cross-section view illustrating another step of a method of manufacturing the capacitor of FIG. 1 according to the first embodiment;

FIG. 9 is a cross-section view illustrating another step of a method of manufacturing the capacitor of FIG. 1 according to the first embodiment;

FIG. 10 is a cross-section view illustrating a step of a method of manufacturing the capacitor of FIG. 1 according to a second embodiment; and

FIG. 11 is a cross-section view illustrating another step of a method of manufacturing the capacitor of FIG. 1 according to the second embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, an etch step enabling to expose a metal layer in order to take an electric contact on a lower electrode of a capacitor of an integrated circuit is here mainly considered. The other steps of the method of manufacturing the capacitor circuit and the integrated circuit are within the abilities of those skilled in the art and will not be described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front,” “back,” “top.” “bottom,” “left,” “right,” etc., or to relative positional qualifiers, such as the terms “above,” “below,” “upper,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and preferably within 5%.

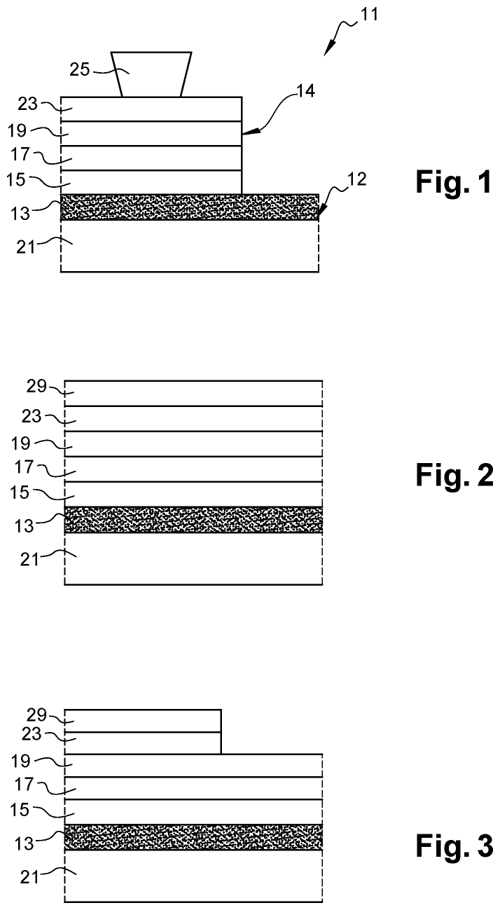

FIG. 1 is a cross-section view of an example of a capacitor 11 according to an embodiment.

Capacitor 11 comprises, in the order from an upper surface 12 of a substrate or support 21:

an electrically-conductive layer 13, also called redistribution layer (RDL);

a first electrode 15 also called lower electrode;

a layer 17 made of a dielectric material; and

a second electrode 19 also called upper electrode.

In the shown example, redistribution layer 13, which may be a conductive layer or may be referred to as a conductive layer, is in contact, by its lower surface, with the upper surface of substrate 21, lower electrode 15 is in contact, by its lower surface, with the upper surface of layer 13, dielectric layer 17 is in contact, by its lower surface, with the upper surface of lower electrode 15, and upper electrode 19 is in contact, by its lower surface, with the upper surface of dielectric layer 17.

According to an aspect of the described embodiments, conductive layer 13 is made of aluminum or of an alloy comprising aluminum, for example, an alloy of aluminum and of copper (AlCu) or an alloy of aluminum, copper, and silicon (AlSiCu). As an example, layer 13 has a thickness in the range from 0.5 μm to 3 μm, preferably equal to approximately 1.5 μm.

Electrodes 15 and 19 may be made of a same material or of different materials. Electrodes 15 and 19 are for example made of tantalum nitride. As a variant, electrodes 15 and/or 19 may be made of polysilicon or of platinum. As an example, electrode 15 has a thickness in the range from 20 nm to 200 nm, preferably in the order of approximately 80 nm. As an example, electrode 19 has a thickness in the range from 20 nm to 200 nm, preferably in the order of approximately 80 nm.

Dielectric layer 17 is for example made of silicon nitride (Si₃N₄) or of tantalum oxynitride (TaON). As an example, dielectric layer 17 has a thickness in the range from 20 nm to 600 nm, preferably equal to approximately 110 nm or to approximately 440 nm.

In the example of FIG. 1, capacitor 11 further comprises:

a conductive layer 23, on top of and in contact with the upper surface of electrode 19; and

a metal pad 25 on top of and in contact with the upper surface of conductive layer 23.

As a variant, upper conductive layer 23 may be omitted such that the metal pad 25 is arranged on top of and in contact with the upper surface of the upper electrode 19 of the capacitor.

Support 21 is for example made of glass or of silicon, preferably highly resistive. Support 21 and layer 13 are for example separated from each other by a dielectric layer, not shown, for example, an oxide layer, for example undoped silicon glass (USG) or any other silicon oxide.

Conductive layer 23 is for example made of aluminum, and has, for example, a thickness in the range from 200 nm to 1 μm, preferably equal to approximately 400 nm. Layer 23 particularly enables to increase the lateral electric conductivity of the upper electrode 19 that it covers.

Metal pad 25 is for example made of copper.

In the shown example, electrodes 15 and 19 and layers 23 and 17 are recessed with respect to conductive layer 13. In other words, a portion of conductive layer 13 is not covered with electrodes 15 and 19 and layers 23 and 17. This enables, during a manufacturing step, not detailed, to take an electric contact, via conductive layer 13, on the lower electrode 15 of the capacitor, for example, by means of a metal wire welded to the upper surface of the exposed portion of layer 13.

As shown in FIG. 1, the layers 15, 17, 19, 23 form a sidewall 14 at which side surfaces of the layers 15, 17, 19, and 23 are substantially coplanar with each other. As shown in FIG. 1, the layers 13, 21 include ends (not shown) at which the layers 13, 21 terminate when extending in a rightward direction. The ends (not shown) of the layers 13, 21 are spaced to the right of the sidewall 14 and the sidewall 14 is spaced to the left of the ends (not shown) of the layers 13, 21. The sidewall 14 is on the upper surface of the conductive layer 13, and the sidewall protrudes away from the conductive layer 13 and the substrate 21.

FIGS. 2, 3, 4, and 5 are cross-section views illustrating successive steps of an example of a method of manufacturing the capacitor 11 of FIG. 1.

FIG. 2 shows an initial stack comprising, successively, support 21, lower conductive layer 13, lower electrode 15, dielectric layer 17, upper electrode 19, upper conductive layer 23, and a protection layer 29, for example, made of resin, covering the upper surface of upper conductive layer 23.

At this stage, the layers of the stack are aligned. In particular, electrodes 15 and 19 and layers 17, 23, and 29 each extend above the entire upper surface of lower conductive layer 13.

FIG. 3 illustrates the structure obtained at the end of a step of local removal of protection layer 29 and of upper conductive layer 23 opposite the portion of lower conductive layer 13.

The local removal of protection layer 29 may be performed by photolithography.

Layer 23 may then be etched by a first chemical plasma etching, for example, by means of a chlorine-based plasma, opposite the opening formed in layer 29, by using layer 29 as an etch mask. In this example, layer 23 is etched across its entire thickness during this first chemical etching.

In the shown example, the first chemical etching is interrupted on the upper surface of electrode 19.

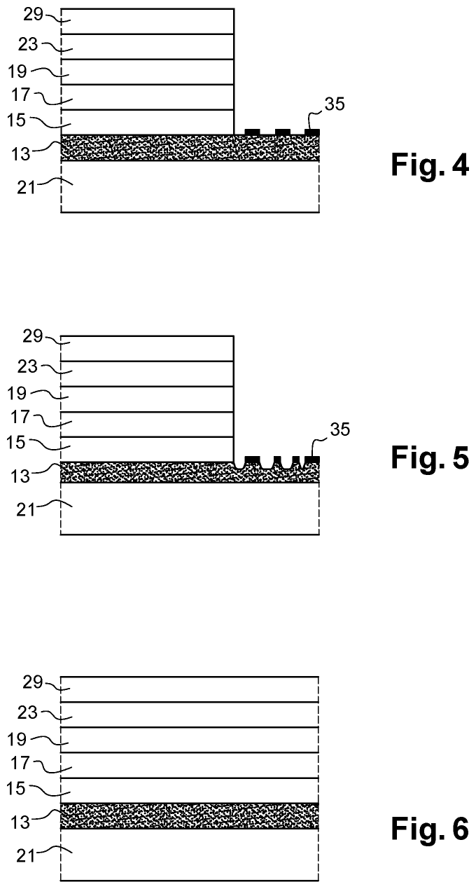

FIG. 4 illustrates the structure obtained at the end of a step of local removal of layers 19, 17, and 15 opposite the portion of lower conductive layer 13 which is desired to be exposed.

Layers 19, 17, and 15 may be etched by a second chemical plasma etching, for example, by means of a fluorine-based plasma, opposite the opening formed in layers 29 and 23, by using layer 29 as an etch mask. In this example, layers 19, 17, and 15 are etched across their entire thickness during this second chemical etching.

In the shown example, the second chemical etching is interrupted on the upper surface of conductive layer 13.

The second fluorine chemical etch step indeed has the advantage of etching layers 19, 17, and 15 selectively over layer 13, containing aluminum.

A disadvantage of this method is that, during the second chemical plasma etching step, the fluorine-based plasma comes into contact with the upper surface of conductive layer 13, containing aluminum. Fluorine atoms then bind to aluminum atoms at the surface of layer 13, creating an aluminum fluoride (A1F) atomic layer 35 at the surface of layer 13. As schematically illustrated in FIG. 4, layer 35 is uneven and does not continuously cover the exposed portion of conductive layer 13.

FIG. 5 illustrates the structure obtained at the end of a subsequent step of wet chemical etching, for example, by means of one or a plurality of acids for example, by means of a solution known under trade name “Pvapox,” comprising a mixture of hydrofluoric acid (HF), of ammonium fluoride (NH₄F), of acetic acid (CH₃COOH), and of benzotriazole (C₆H₅N₃).

This wet chemical etching may for example be used to locally remove, opposite the upper surface of conductive layer 13, a passivation layer (not shown in the drawings) previously deposited on the upper surface of the structure of FIG. 4.

The wet chemical etching is for example preceded by a step (not detailed in the drawings) of deposition of a layer of an oxide, for example, a USG layer over the entire structure. The step of wet chemical etching particularly enables to remove a portion of the oxide layer located on top of and in contact with the upper surface of the portion of layer 13 exposed at the plasma etch step of FIG. 4.

The etch solution used at the step of FIG. 5 tends to superficially consume the exposed portion of conductive layer 13. However, this surface etching is blocked by the aluminum fluoride residues 35 which are resistant to the solution used and more generally to acid attacks.

A micro-masking phenomenon resulting in the forming of unevennesses on the upper surface of conductive layer 13.

These unevennesses degrade the quality of the electric contact subsequently taken on the upper surface of layer 13. In particular, these unevennesses do not allow a good electric connection between a wire and layer 13 by means of a welding.

FIGS. 6, 7, 8, and 9 are cross-section views illustrating successive steps of an example of a method of manufacturing the capacitor 11 of FIG. 1 according to a first embodiment.

FIG. 6 illustrates an initial stack identical to the stack illustrated in FIG. 2.

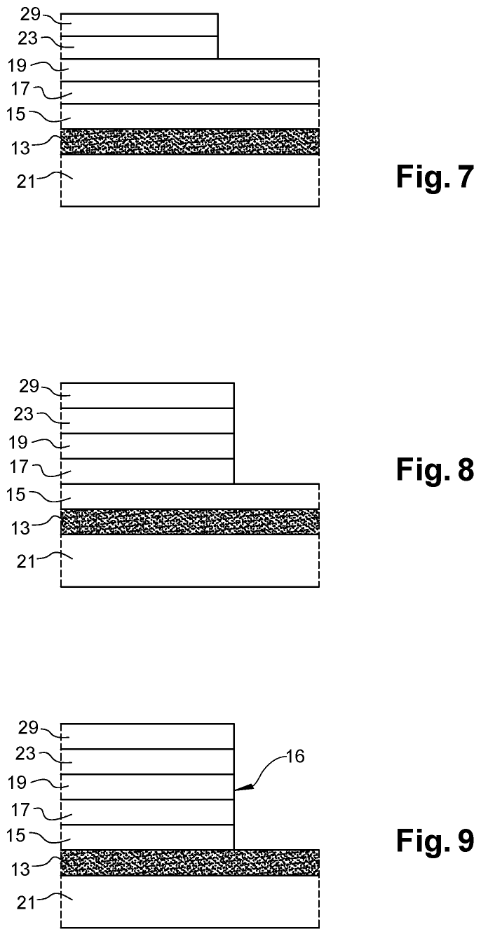

FIG. 7 illustrates the structure obtained at the end of a step of local removal of protection layer 29 and of upper conductive layer 23 opposite the portion of lower conductive layer 13 which is desired to be discussed.

These steps are for example identical or similar to the steps described hereabove in relation with FIG. 3.

In particular, the local removal of protection layer 29 may be performed by photolithography. Layer 23 may then be etched by a first chemical plasma etching, for example by means of a chlorine-based plasma, opposite the opening formed in layer 29.

In the shown example, the first chemical etching is interrupted on the upper surface of electrode 19.

FIG. 8 illustrates the structure obtained at the end of a step of local removal of layers 19 and 17 opposite the portion of lower conductive layer 13 which is desired to be exposed.

Layers 19 and 17 may be etched by a second chemical plasma etching, for example, by means of a fluorine-based plasma, similarly to what has been described hereabove in relation with FIG. 4.

In this example, layers 19 and 17 are etched across their entire thickness during this second chemical etching.

Unlike what has been previously described in relation with FIG. 4, in this example, the second chemical plasma etching is interrupted before reaching the upper surface of lower conductive layer 13.

In the shown example, the second chemical plasma etching is interrupted on the upper surface of lower electrode 15.

The second chemical plasma etching is for example similar to what has been described hereabove in relation with FIG. 4. As an example, the second chemical plasma etching is carried out by means of a fluorine-based plasma.

The second chemical etching step being stopped or seized before emerging onto layer 13, the fluorine-based plasma does not come into contact with layer 13, which enables to avoid the forming of aluminum fluorine layer 35 (FIG. 4).

FIG. 9 illustrates the structure obtained at the end of a step of local removal of lower electrode layer 15 opposite the portion of lower conductive layer 13 which is desired to be exposed.

In this example, layer 15 is removed by physical plasma etching, by means of a plasma of a gas having no affinity for aluminum, for example, a plasma of a neutral gas, for example, an argon or nitrogen plasma, preferably an argon plasma. In this example, the physical etching is induced by ions of the neutral gas, for example, argon ions, accelerated by a bias voltage.

The speed of physical etching of electrode 15 is for example equal to approximately 50 nm/min while it is ten times greater during a fluorine chemical plasma etching and fifteen times greater than during a chlorine chemical plasma etching.

In this example, the physical plasma etching is interrupted when the upper surface of conductive layer 13 is exposed, that is, when electrode 15 has been etched across its entire thickness.

An advantage of the method described in relation with FIGS. 6 to 9 is that it is emerged onto conductive layer 13 by means of a neutral physical plasma etching. This enables to avoid the forming of aluminum fluoride on the exposed surface of conductive layer 13. Thus, the forming of unevennesses on the upper surface of conductive layer 13, such as described in relation with FIG. 5, can be avoided. This enables to form a more reliable and higher-performance electric connection on the upper surface of layer 13.

As a variant, not shown, the first chemical plasma etching (FIG. 7) may be carried on through all or part of the thickness of upper electrode 19 and interrupted in electrode 19 or on the upper surface of dielectric layer 17.

In another variant, not shown, the first chemical plasma etching may be carried on through all or part of the thickness of dielectric layer 17 and interrupted in dielectric layer 17 or on the upper surface of electrode 15.

In another variant, not shown, the second chemical plasma etching step (FIG. 8) is interrupted before reaching the upper surface of electrode 15, for example, on the upper surface of dielectric layer 17 or in dielectric layer 17.

In another variant, not shown, a portion of the thickness of electrode 15 is removed during the second chemical plasma etching step. In other words, the second chemical plasma etching step is interrupted in lower electrode layer 15.

As an example, the first chemical plasma etching step is implemented in a first etching tool and the second chemical plasma etching step and the physical plasma etching step are implemented in a second etching tool different from the first tool.

In this case, a purging of the etch chamber of the second tool may be carried out between the second chemical plasma etching step and the physical plasma etching step, to avoid for fluorine atoms to remain in the etch chamber during the physical plasma etching step. The purging for example has a duration in the range from 10 seconds to 20 seconds.

It should be noted that in the case where the upper aluminum-based conductive layer 23 is omitted, the first step of chemical plasma etching, by means of a chlorine-based plasma, may be omitted. In other words, two etch steps may be provided, that is, the second step of chemical plasma etching (FIG. 8), by means of a fluorine-based plasma, and the step of physical plasma etching (FIG. 9), by means of a neutral gas plasma, for example, an argon plasma.

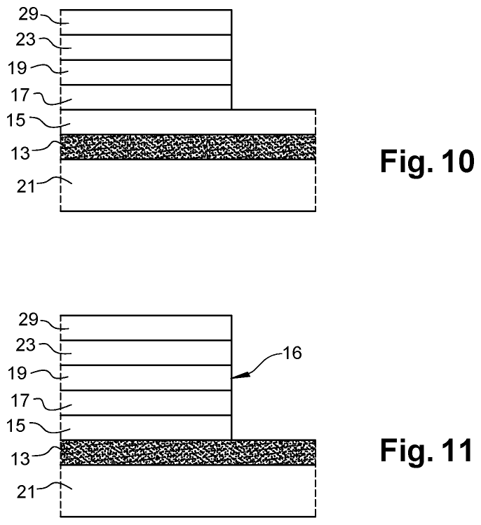

FIGS. 10 and 11 are cross-section views illustrating successive steps of an example of a method of manufacturing the capacitor 11 of FIG. 1 according to a second embodiment.

In this second embodiment, the second step of chemical plasma etching, by means of a fluorine-based plasma, is omitted. In other words, only two etch steps are provided, that is, the first step of chemical plasma etching, by means of a chlorine-based plasma, and the step of physical plasma etching, by means of a neutral gas plasma, for example, an argon plasma.

As an example, it is started from an initial stack similar to that of FIG. 6.

FIG. 10 illustrates the structure obtained at the end of a step of local removal of protection layer 29 and of layers 23, 19, and 17 opposite the portion of the lower conductive layer 13 which is desired to be exposed.

The local removal of protection layer 29 may be performed by photolithography.

Layers 23, 19, and 17 may then be etched by a first chemical plasma etching, for example, by means of a chlorine-based plasma, opposite the opening formed in layer 29, by using layer 29 as an etch mask.

The first chemical plasma etching is interrupted before reaching the upper surface of lower conductive layer 13.

In the shown example, the first chemical plasma etching is interrupted on the upper surface of lower electrode 15.

FIG. 11 illustrates the structure obtained at the end of a step of local removal of lower electrode layer 15 opposite the portion of lower conductive layer 13 which is desired to be exposed.

In this example, layer 15 is removed by physical plasma etching, similarly to what has been described hereabove in relation with FIG. 9.

In this example, a side surface of the layer 15 is substantially coplanar with respective side surfaces of the layers 17, 19, 23, 29 forming a sidewall 16 of these respective side surfaces of the layers 17, 19, 23, 29 and the side surface of the layer 15. The sidewall 16 may be seen in FIGS. 9 and 11 of the present disclosure.

As a variant, not shown, the first chemical plasma etching (FIG. 10) may be interrupted before reaching the upper surface of electrode 15, for example, on the upper surface of dielectric layer 17 or in dielectric layer 17.

In another variant, not shown, a portion of the thickness of electrode 15 is removed during the first chemical plasma etching step.

As shown in FIGS. 4, 5, 9, and 11, the protection layer 29 may be removed from the upper surface of the conductive layer 23 and the metal pad 25 may be formed on the conductive pad. When the conductive layer 23 is omitted, the metal pad 25 may be formed on the upper electrode 19.

Various embodiments and variants have been described. Those skilled in the art will understand that certain features of these various embodiments and variants may be combined, and other variants will occur to those skilled in the art. In particular, the described embodiments are not limited to the examples of numerical values or to the examples of materials mentioned in the present disclosure.

Finally, the practical implementation of the described embodiments and variations is within the abilities of those skilled in the art based on the functional indications given hereabove.

A method of manufacturing a capacitor, may be summarized as including the successive steps of a) forming a stack including, in the order from the upper surface of a substrate (21), a first conductive layer (13) made of aluminum or an aluminum-based alloy, a first electrode (15), a first dielectric layer (17), and a second electrode (19); b) etching, by chemical plasma etching, an upper portion of the stack, said chemical plasma etching being interrupted before the upper surface of the first conductive layer (13); and c) etching, by physical plasma etching, a lower portion of the stack, said physical plasma etching being interrupted on the upper surface of the first conductive layer (13).

At step b), said chemical plasma etching may include a first step of chemical plasma etching by means of a chlorine-based plasma, followed by a second step of chemical plasma etching by means of a fluorine-based plasma.

The second chemical plasma etching step and the physical plasma etching step may be implemented in a same etch chamber, a step of purging of said etching chamber being implemented between the two steps.

At step b), said chemical plasma etching may include a single step of chemical plasma etching by means of a chlorine-based plasma.

At step b), said chemical plasma etching may include a single step of chemical plasma etching by means of a fluorine-based plasma.

The stack may further include a second conductive layer (23) coating the second electrode.

At step c), the physical plasma etching may be performed by means of an argon plasma.

The second conductive layer (23) may be made of aluminum or of an alloy comprising aluminum.

The first electrode (15) may be made of tantalum nitride.

Said lower portion of the stack may include at least a portion of the thickness of the first electrode (15).

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming a capacitor including:
forming a stack including:
forming a first conductive layer includes aluminum or an aluminum-based alloy on the first surface of a substrate;
forming a first electrode on the first conductive layer;
forming a first dielectric layer on the first electrode; and
forming a second electrode on the first dielectric layer;
etching, by chemical plasma etching, a first portion of the stack, the chemical plasma etching being seized before reaching a second surface of the first conductive layer; and
etching, by physical plasma etching, a lower portion of the stack, the physical plasma etching being seized at the second surface of the first conductive layer.

2. The method according to claim 1, wherein the chemical plasma etching comprises a chlorine-based chemical plasma etching step, followed by a fluorine-based chemical plasma etching step.

3. The method according to claim 2, wherein the fluorine-based chemical plasma etching step and the physical plasma etching step are implemented in an etch chamber.

4. The method according to claim 3, further comprising a purging step in which the etching chamber is purged after the fluorine-based chemical plasma etching step and before the physical plasma etching step.

5. The method according to claim 1, wherein the chemical plasma etching comprises a chlorine-based chemical plasma etching step.

6. The method according to claim 1, wherein the chemical plasma etching comprises a fluorine-based chemical plasma etching step.

7. The method according to claim 1, wherein the stack further comprises a second conductive layer on and extending along the second electrode.

8. The method according to claim 1, wherein the physical plasma etching is an argon-based physical plasma etching.

9. The method according to claim 1, wherein the second conductive layer is made of aluminum or of an alloy including aluminum.

10. The method according to claim 1, wherein the first electrode is made of tantalum nitride.

11. The method according to claim 1, wherein the lower portion of the stack comprises at least a portion of the thickness of the first electrode.

12. A device, comprising:
a stacked capacitor structure including:
a substrate having a surface;
a first conductive layer on and extending along the surface;
a first electrode on and extending along the conductive layer;
a dielectric layer on and extending along the first electrode;
a second electrode on and extending along the dielectric layer;
a second conductive layer on and extending along the second electrode; and
a metal pad on and extending from the second conductive layer.

13. The device of claim 12, wherein the stacked capacitor further comprising a sidewall includes respective side surfaces of the first conductive layer, the first electrode, the dielectric layer, the second electrode, and the second conductive layer are substantially coplanar with each other.

14. The device of claim 13, wherein:
the substrate further comprises a first end spaced apart from the sidewall;
the first conductive layer further comprises a second end spaced apart from the sidewall; and
the sidewall is on the first conductive layer.

15. A method, comprising:
forming a stacked structure including:
forming a first conductive layer on a first surface of a substrate;
forming a first electrode on the first conductive layer;
forming a dielectric layer on the first electrode;
forming a second electrode on the dielectric layer; and
forming a protection layer covering the second electrode, the dielectric layer, the first electrode, and the first conductive layer;
forming a sidewall including forming respective side surfaces of the first electrode, the dielectric layer, the second electrode, and the protection layer by removing respective portions of the first electrode, the dielectric layer, the second electrode, the second conductive layer, and the protection layer, respectively.

16. The method according to claim 15, wherein removing the respective portion of the protection layer includes a photolithography step.

17. The method according to claim 15, wherein removing the respective portions of first electrode, the dielectric layer, and the second electrode includes an etching step.

18. The method according to claim 17, wherein the etching step includes etching the second electrode and the dielectric layer utilizing a chlorine-based chemical plasma etching followed by etching the conductive layer utilizing a fluorine-based chemical plasma etching.

19. The method according to claim 18, wherein the chlorine-based chemical plasma etching is terminated before reaching the first conductive layer.

20. The method according to claim 15, wherein:
forming the stacked structure further includes forming a second conductive layer on the second electrode;
forming the protection layer further includes forming the protection layer on the second conductive layer; and
forming the sidewall further includes forming a respective side surface of the second conductive layer by removing a respective portion of the second conductive layer.
